(19) United States
(12) Patent Application Publication
(10) Pub. No.: US 2025/0008825 A1
(43) Pub. Date: Jan. 2, 2025

(54) DISPLAY PANEL AND DISPLAY DEVICE

(71) Applicant: Wuhan Tianma Micro-Electronics Co., Ltd., Wuhan (CN)

(72) Inventor: Huiping CHAI, Wuhan (CN)

(21) Appl. No.: 18/414,684

(22) Filed: Jan. 17, 2024

(30) Foreign Application Priority Data
Jun. 28, 2023 (CN) 202310782816.3

(51) Int. Cl. H10K 59/80; H10K 59/122; H10K 59/40

(52) U.S. Cl. CPC H10K 59/8792; H10K 59/122; H10K 59/40

(57) ABSTRACT

A display panel and a display device are provided. The display panel includes a substrate, and a display layer and a black matrix layer arranged sequentially on a same side of the substrate. The display layer includes a pixel definition layer defining a plurality of pixel openings. In a first direction, the plurality of pixel openings pass through the pixel definition layer and the first direction is perpendicular to a plane where the substrate is located. The black matrix layer includes a matrix opening that overlaps with a pixel opening in the first direction and a light-shielding member that does not overlap with the pixel opening in the first direction. The light-shielding member includes an openwork opening; and the matrix opening and the openwork opening are both located in a display area of the display panel.

### CROSS-REFERENCE TO RELATED APPLICATION

This application claims the priority of Chinese Patent Application No. 202310782816.3, filed on Jun. 28, 2023, the content of which is incorporated by reference in its entirety.

### TECHNICAL FIELD

The present disclosure generally relates to the field of display technologies and, more particularly, relates to a display panel and a display device.

### BACKGROUND

Organic light-emitting diodes (OLEDs) have the advantages of flexible preparation, low driving voltage, and low power consumption. In recent years, OLED technologies have advanced rapidly, and their broad application prospects have made OLED devices one of the most popular research topics in the developments of flat-panel displays, new lighting, wearables, and smart electronic products.

In the OLED technologies, circular polarizers are introduced into organic light-emitting display panels to reduce external ambient light reflection. However, circular polarizers have problems including low transmittance and large thickness. To solve such problems, some products introduce a color film layer into the organic light-emitting display panel to replace the circular polarizer, and utilize the filtering principle of the color film and the light absorption principle of the black matrix in the color film layer to play an anti-reflective role and to solve the problems of low transmittance and large thickness of the circular polarizers.

With the development of display technology, users have higher and higher requirements for the transmittance of organic light-emitting display products. How to further improve the transmittances of the aforementioned display products has become one of the technical problems that urgently needs to be solved at this stage. The present disclosed display panel and display devices are direct to solve one or more problems set forth above and other problems in the arts.

### SUMMARY

One aspect of the present disclosure provides a display panel. The display panel includes a substrate, and a display layer and a black matrix layer arranged sequentially on a same side of the substrate. The display layer includes a pixel definition layer; and the pixel definition layer defines a plurality of pixel openings. In a first direction, the plurality of pixel openings pass through the pixel definition layer; and the first direction is perpendicular to a plane where the substrate is located. The black matrix layer includes a matrix opening that overlaps with a pixel opening of the plurality of pixel openings in the first direction and a light-shielding member that does not overlap with the pixel opening in the first direction; the light-shielding member includes an openwork opening; and the matrix opening and the openwork opening are both located in a display area of the display panel.

Another aspect of the present disclosure provides a display device. The display device includes a display panel. The display panel includes a substrate, and a display layer and a black matrix layer arranged sequentially on a same side of the substrate. The display layer includes a pixel definition layer; the pixel definition layer defines a plurality of pixel openings. In a first direction, the plurality of pixel openings pass through the pixel definition layer; and the first direction is perpendicular to a plane where the substrate is located. The black matrix layer includes a matrix opening that overlaps with a pixel opening of the plurality of pixel openings in the first direction and a light-shielding member that does not overlap with the pixel opening in the first direction; the light-shielding member includes an openwork opening; and the matrix opening and the openwork opening are both located in a display area of the display panel.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates a top view of an exemplary display panel according to various disclosed embodiments of the present disclosure;

FIG. 2 illustrates an AA-sectional view of the display panel in FIG. 1;

FIG. 3 illustrates a top view of a pixel definition layer of an exemplary display panel according to various disclosed embodiments of the present disclosure;

FIG. 4 illustrates a top view of a black matrix layer of an exemplary display panel according to various disclosed embodiments of the present disclosure;

FIG. 5 illustrates a BB-sectional view in FIG. 4;

FIG. 6 illustrates another BB-sectional view in FIG. 4;

FIG. 7 illustrates a top view of an exemplary touch electrode according to various disclosed embodiments of the present disclosure;

FIG. 8 illustrates a zoomed-in view of an exemplary light-shielding member corresponding to an array opening;

FIG. 9 illustrates a zoomed-in view of another exemplary light-shielding member corresponding to an array opening;

FIG. 10 illustrates a zoomed-in view of another exemplary light-shielding member corresponding to an array opening;

FIG. 11 illustrates a zoomed-in view of another exemplary light-shielding

member corresponding to an array opening;

FIG. 12 illustrates a zoomed-in view of another exemplary light-shielding member corresponding to an array opening;

FIG. 13 illustrates a zoomed-in view of another exemplary light-shielding member corresponding to an array opening;

FIG. 14 illustrates a zoomed-in view of another exemplary light-shielding member corresponding to an array opening;

FIG. 15 illustrates a zoomed-in view of another exemplary light-shielding member corresponding to an array opening;

FIG. 16 illustrates a zoomed-in view of another exemplary light-shielding member corresponding to an array opening;

FIG. 17 illustrates a zoomed-in view of another exemplary light-shielding member corresponding to an array opening;

FIG. 18 illustrates an exemplary structure of which top of two light-shielding members adjacent to a same array opening are both disposed with second openwork openings;

FIG. 19 illustrates a configuration that the second openwork opening in FIG. 18 is filled with a color resistor;

FIG. 20 illustrates a CC-sectional view corresponding to FIG. 19;

FIG. 21 illustrates an exemplary top view of a pixel opening corresponding to the array opening in FIG. 19 of the display panel according to various disclosed embodiments of the present disclosure;

FIG. 22 illustrates another configuration that the second openwork opening in FIG. 18 is filled with a color resistor;

FIG. 23 illustrates an exemplary DD-sectional view corresponding to FIG. 22;

FIG. 24 illustrates another exemplary top view of a pixel opening corresponding to the array opening of the display panel according to various disclosed embodiments of the present disclosure;

FIG. 25 illustrates an exemplary distribution of the sub-pixels and the openwork openings according to various disclosed embodiments of the present disclosure;

FIG. 26 illustrates another exemplary distribution of the sub-pixels and the openwork openings according to various disclosed embodiments of the present disclosure; and

FIG. 27 illustrates an exemplary display device according to various disclosed embodiments of the present disclosure.

### DETAILED DESCRIPTION

Various exemplary embodiments of the present disclosure will now be described in detail with reference to the accompanying drawings. It should be noted that the relative arrangements of components and steps, numerical expressions and numerical values set forth in these embodiments do not limit the scope of the present disclosure unless specifically stated otherwise.

The following description of at least one exemplary embodiment is merely illustrative in nature and in no way taken as limiting the disclosure, its application or uses.

Techniques, methods and devices known to those of ordinary skill in the relevant art may not be discussed in detail, but where appropriate, such techniques, methods and devices should be considered parts of the description.

In all examples shown and discussed herein, any specific values should be construed as exemplary only, and not as limitations. Therefore, other instances of the exemplary embodiment may have different values.

It should be noted that like numerals and letters denote like items in the following figures. Therefore, once an item is defined in one figure, it does not require further discussion in subsequent figures.

It will be apparent to those skilled in the art that various modifications and variations can be made in the present disclosure without departing from the spirit or scope of the disclosure. Thus, it is intended that the present disclosure covers the modifications and variations of this disclosure provided they come within the scope of the corresponding claims (claimed technical solutions) and their equivalents. It should be noted that the implementation modes provided by the embodiments of the present disclosure can be combined with each other if there is no contradiction.

It should be noted that similar reference numerals and letters refer to similar items in the following figures, so that once an item is defined in one figure, it does not need further discussion in subsequent figures.

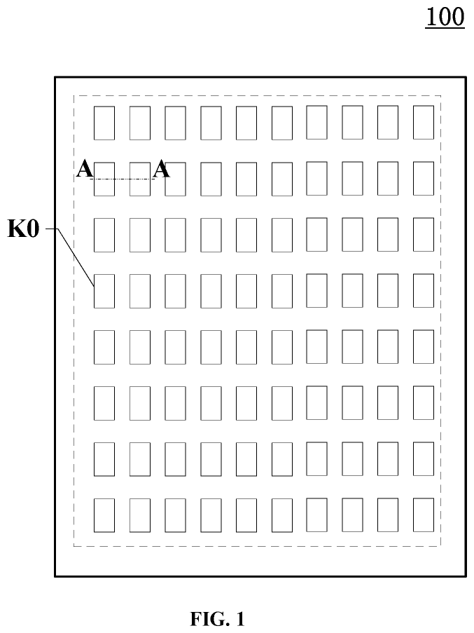

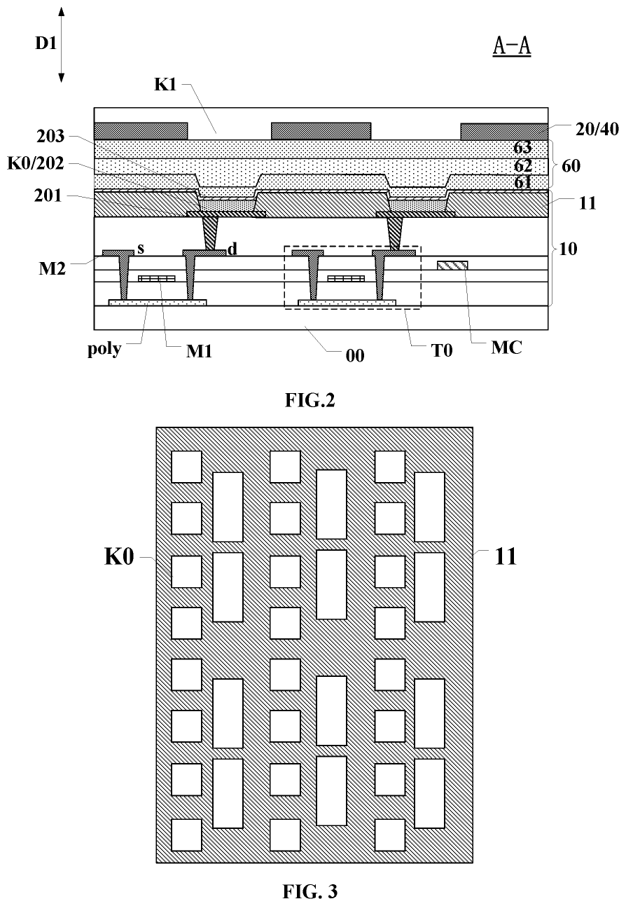

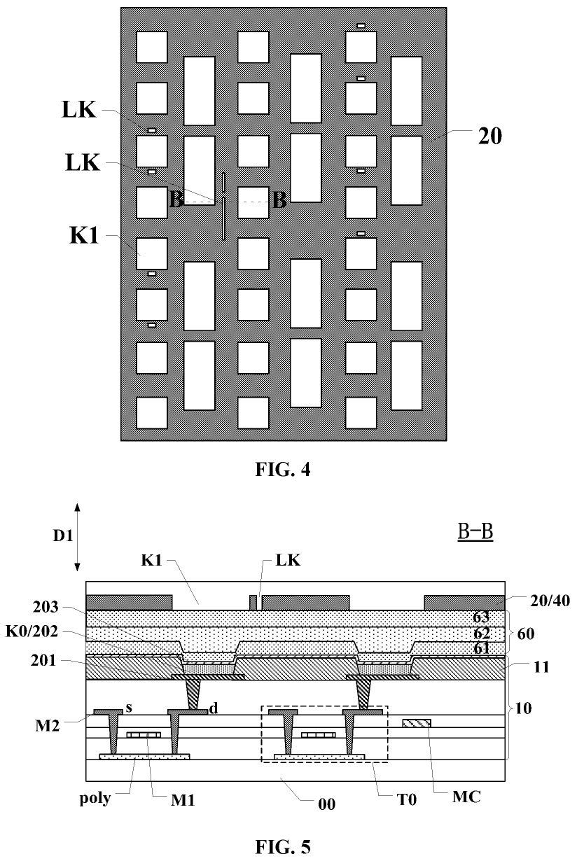

The present disclosure provides a display panel and a display device. FIG. 1 illustrates a top view of an exemplary display panel provided by an embodiment of the present disclosure. FIG. 2 illustrates an AA-sectional view of the display panel in FIG. 1. FIG. 3 illustrates an exemplary top view of a pixel definition layer of a display panel provided by an embodiment of the present disclosure. FIG. 4 illustrates an exemplary top view of a black matrix layer of the display panel provided by an embodiment of the present disclosure. FIG. 5 shows a BB-sectional view of FIG. 4.

It should be noted that the embodiment shown in FIG. 1 only illustrates the display panel of the present disclosure by taking a rectangular-shaped display panel as an example and does not limit the specific structure of the display panel of the present disclosure. In some other embodiments of the present disclosure, the shape of the display panel may also be embodied as a rounded rectangle, a circle, an ellipse, or other structures including arc edges, which are not specifically limited by the present disclosure. The cross-sectional structure in FIG. 2 only illustrates a relative positional relationship between the substrate 00, the display layer 10 and the black matrix layer 20, and does not limit the actual film layer structure of the display panel. FIG. 3 and FIG. 4 only illustrate the partial areas of the pixel definition layer 11 and the black matrix layer 20 in the display panel, and do not represent the actual number of pixel openings K0, array openings K1 and openwork openings LK included in the display panel. In addition, the arrangement of the pixel openings K0 and the array openings K1 is only illustrative, and does not limit the actual pixel arrangement structure and opening shape of the display panel. The position, shape and size of the openwork opening LK are also illustrative. This embodiment only takes the openwork opening LK as a rectangle as an example for description. In some other embodiments of the present disclosure, the openwork opening LK may also be embodied in a circular, oval or other non-rectangular structure.

As shown in FIGS. 1-5, the present disclosure provides a display panel 100. The display panel 100 may include a substrate 00, and a display layer 10 and a black matrix layer 20 that may be sequentially disposed on a same side of the substrate 00.

The display layer 10 may include a pixel definition layer 11. The pixel definition layer 11 may define a plurality of pixel openings K0. The pixel opening K0 may pass through the pixel definition layer 11 in a first direction D1. The first direction D1 may be perpendicular to the plane where the substrate 00 is located.

The black matrix layer 20 may include a matrix opening K1 that overlaps with the pixel opening K0 in the first direction D1 and a light-shielding member 40 that may not overlap with the pixel opening K0 in the first direction D1. The light-shielding member 40 may include an openwork opening LK. The matrix opening K1 and the openwork opening LK may be located in the display area of the display panel.

In one embodiment, the display panel may be a display panel using the organic light-emitting diode display technology, i.e., an organic light-emitting diode (OLED) display panel. The basic structure of the light-emitting functional layer of the OLED display panel may include an anode 201, a light-emitting material layer 202 and a cathode 203. The light-emitting material layer 202 may be located in the pixel opening K0, and the anode 201 and the cathode 203 may be respectively located on both sides of the light-emitting material layer 202. When the power supply supplies an appropriate voltage, the holes in the anode 201 and the electrons in the cathode 203 may combine in the light-emitting material layer 202 to generate bright light. Compared with thin-film field-effect transistor liquid crystal displays, OLED display devices have the characteristics of high visibility and high brightness, and are more power-saving, lightweight, and thin. In one embodiment, an encapsulation layer 60 may also be provided on the side of the cathode 203 away from the anode 201. The encapsulation layer 50 may be a thin-film encapsulation layer, including a first inorganic layer 61, an organic layer 62 and a second inorganic layer 63, to isolate water and oxygen and prevent external moisture and oxygen from affecting the light-emitting material layer 202. The black matrix layer 20 in this embodiment may be disposed on the side of the encapsulation layer 60 away from the display layer 10. In one embodiment, the display layer 10 may further include a first metal layer M1, a capacitive metal layer MC and a second metal layer M2 disposed between the substrate 00 and the pixel definition layer 11. The first metal layer M1 may be, for example, a gate metal layer, and the gates of the transistors in the display panel may be disposed on the first metal layer M1. The capacitive metal layer MC may be configured to form a capacitor structure with the first metal layer M1 or the second metal layer M2. The source electrode s and the drain electrode d of the transistor T0 in the display panel may be located on the second metal layer M2. The semiconductor layer poly may include a source region and a drain region. The source region and the drain region may be formed by being doped with N-type or P-type impurity ions. The source electrode s of the transistor T0 may be electrically connected to the source region of the semiconductor layer poly through the contact hole, and the drain electrode d of the transistor T0 may be electrically connected to the drain region of the semiconductor layer poly through the contact hole. It should be noted that FIG. 2 and FIG. 5 only illustrate a possible film structure of the display layer 10 and do not limit the actual film structure and number of film layers of the display layer 10.

Further, referring to FIGS. 1-5, in one embodiment of the present disclosure, the pixel opening K0 of the pixel definition layer 11 may be set corresponding to the matrix opening K1 of the black matrix layer 20, and the light emitted by the light-emitting material layer 202 in the pixel opening K0 may pass through the matrix opening K1 and irradiate towards the light-emitting surface of the display panel. When the black matrix layer 20 is introduced in the light-emitting direction of the display layer 10, and when external light irradiates the light-shielding member 40 of the black matrix layer 20, the light-absorbing effect of the light-shielding member 40 may effectively reduce the reflection of the display panel and improve the anti-reflection performance of the display panel under relatively strong light. Further, after the introduction of the black matrix layer 20, there may be no need to install a thick circular polarizer, which may be beneficial to realizing a thin design of the display panel.

Further, in the display panel provided by one embodiment of the present disclosure, the light-shielding member 40 of the black matrix may be provided with an openwork opening LK. A portion of the light emitted by the light-emitting material layer 202 in the pixel definition layer 11 may be emitted through the above-mentioned openwork opening LK. Therefore, it may be beneficial to improve the transmittance of the display panel and increase the overall light-emission amount of the display panel, and it may be beneficial to improve the display effect of the display panel.

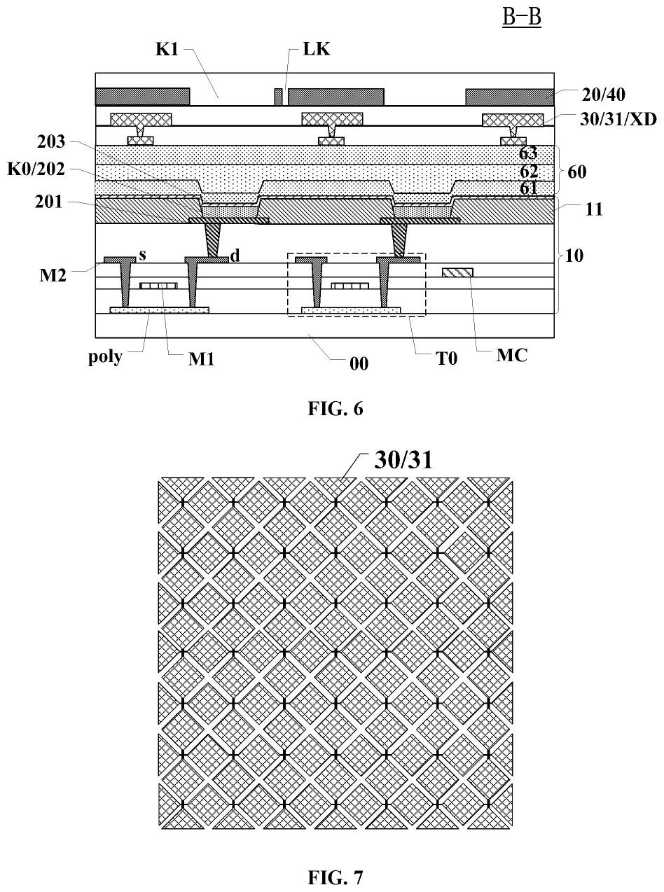

FIG. 6 illustrates another exemplary BB-sectional view of the display panel in FIG. 4. FIG. 7 shows a top view of the touch electrode. As shown in FIGS. 6-7, in one embodiment of the present disclosure, the display panel may also include a touch layer 30, and the touch layer 30 may be located between the display layer 10 and the black matrix layer 20.

The touch layer 30 may include a plurality of touch electrodes 31. The touch electrodes 31 may include a plurality of electrically connected metal line segments XD. In the first direction D1, the orthographic projections of the metal line segments XD on the plane where the substrate 00 is located and the orthographic projections of the pixel opening K0 and the matrix opening K1 and the openwork opening LK on the plane where the substrate 00 is located may not overlap, and the orthographic projection of the metal line segment XD on the substrate 00 may be located within the orthographic projection of the light-shielding member 40 on the substrate 00.

This embodiment shows a solution of introducing a touch layer into the display panel such that the display panel has a display function. The touch layer 30 may be located between the display layer 10 and the black matrix layer 20. When the display panel includes the encapsulation layer 60, the touch layer 30 may be located between encapsulation layer 60 and the black matrix layer 20. The touch electrodes 31 in the touch layer 30 may include a plurality of electrically connected metal line segments XD. For example, the touch electrodes 31 may be a grid-like structure. FIG. 6 only takes mutual capacitance touch electrodes as an example for illustration, but the type of touch electrodes may not be limited. In some other embodiments of the present disclosure, the touch electrodes may also be embodied as self-capacitive touch electrodes. In one embodiment, it may be defined that the metal line segment XD in the touch electrode may not overlap with the pixel opening K0, the matrix opening K1, and the openwork opening LK. For example, no touch electrode may be provided in the light-emission direction corresponding to the pixel opening K0. It may be helpful to avoid the impact of the touch electrode on the aperture ratio of the display panel, and it may be also helpful to avoid the problem of visible metal line segment in the touch electrode.

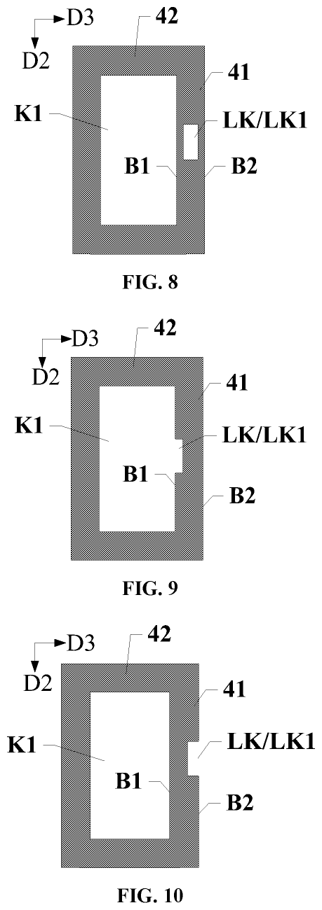

FIG. 8 shows an enlarged schematic diagram of the light-shielding member 40 corresponding to one matrix opening K1. This embodiment illustrates the relative positional relationship between the light-shielding member 40, the matrix opening K1 and the openwork opening LK, but does not limit the actual shapes and sizes of the matrix opening K1, the light-shielding member 40 and the openwork openings LK, and the actual number of the openwork openings LK included in the light-shielding member 40 may not be limited.

Further, referring to FIG. 8, in one embodiment of the present disclosure, the light-shielding member 40 may include first light-shielding members 41 and second light-shielding members 42 arranged crosswise. The first light-shielding members 41 may extend in the second direction D2 and may be arranged in a third direction D3. The second light-shielding members 42 may extend in the third direction D3 and may be arranged in the second direction D2. The second direction D2 and the third direction D3 may intersect. The openwork opening LK may be located in the first light-shielding member 41 and/or the second light-shielding member 42.

Specifically, this embodiment takes a matrix opening K1 with a rectangular structure as an example. The first light-shielding member 41 and the second light-shielding member 42 defining the matrix opening K1 may extend along the second direction D2 and the third direction D3 respectively. When the openwork opening LK is introduced into the light-shielding member 40, the openwork opening LK may be located only on the first light-shielding member 41, or only on the second light-shielding member 42, or on both the first light-shielding member 41 and the second light-shielding member 42. In this embodiment, the configuration that the openwork opening LK is located on the first light-shielding member 41 is used as an example for description. Other possible arrangements of the openwork opening LK will be further described later. When the openwork opening LK is introduced into the light-shielding member 40, the display panel may not have metal wirings or components in the orthographic projection area corresponding to the openwork opening LK in the first direction D1, and when the light-emitting material in the pixel opening K0 corresponding to the matrix opening K1 emits light, a portion of the light may be emitted through the openwork opening LK, which may help increase the overall transmittance of the display panel.

Further, referring to FIG. 8, in one embodiment of the present disclosure, the openwork opening LK may include at least one first openwork opening LK1 located in the first light-shielding member 41. The first openwork opening LK1 may include two openings extending in the second direction D2. The first light-shielding member 41 may include a first side B1 and a second side B2 that are oppositely arranged in the third direction D3 and extend in the second direction D2. At least one side of the first openwork opening LK1 extending in the second direction D2 may be located between the first side B1 and the second side B2.

Assuming that the openwork opening LK provided on the first light-shielding member 41 is the first openwork opening LK1, this embodiment may limit the specific shape of the first openwork opening LK1. The first light-shielding member 41 may extend as a whole in the second direction D2. In one embodiment, the long axis direction of the first openwork opening LK1 may be the second direction D2. The two sides of the first light-shielding member 41 extending along the second direction D2 may be respectively the first side B1 and the second side B2. The first openwork opening LK1 may also include two sides extending in the second direction D2, and at least one of the two sides may be located between the first side B1 and the second side B2 of the first light-shielding member 41. When the long axis direction of the first openwork opening LK1 provided on the first light-shielding member 41 is arranged along the extending direction of the first light-shielding member 41, the area of the first openwork opening LK1 may be appropriately increased, and the fabrication difficulty of the first openwork opening LK1 may be reduced appropriately; and it may be conducive to improving the transmittance of the display panel when the area of the first openwork opening LK1 increases.

Further, referring to FIG. 8, in one embodiment of the present disclosure, the two sides extending in the second direction D2 of the first openwork opening LK1 may be both located between the first side B1 and the second side B2.

Referring to FIG. 5 and FIG. 8, when the two sides of the first openwork opening LK1 extending in the second direction D2 are arranged between the first side B1 and the second side B2 of the first light-shielding member 41, the first openwork opening LK1 may not be connected to the matrix opening K1. When the light-emitting material layer at the side of the matrix opening K1 facing toward on the display layer 10 emits light, most of the light may pass through the matrix opening K1 and be directed to the light-exiting surface of the display panel, and some of the light may be able to pass through the first openwork opening LK1 and irradiate toward the light-emitting surface of the display panel, which may be beneficial to increasing the transmittance of the display panel and increasing the overall light-emitting amount of the display panel.

FIG. 9 and FIG. 10 respectively show another enlarged schematic view of the light-shielding member 40 corresponding to one matrix opening K1. The difference between

FIG. 9 and FIG. 10 may include that the position of the first openwork opening LK1 on the first light-shielding member 41 may be different. Specifically, the embodiment shown in FIG. 9 shows a solution in which one side of the first openwork opening LK1 extending in the second direction D2 coincides with the first side B1 of the first light-shielding portion 41. The embodiment shown in FIG. 10 shows a solution in which one side of the openwork opening LK1 extending along the second direction D2 may overlap with the second side B2 of the first light-shielding member 41.

Referring to FIG. 9 and FIG. 10, in one embodiment of the present disclosure, one of the two sides of the first openwork opening LK1 extending along the second direction D2 may be located between the first side B1 and the second side B2. The other side of the openwork opening LK1 extending along the second direction D2 may coincide with the first side B1 or the second side B2. It should be noted that the first side B1 and the second side B2 of the first light-shielding member 41 mentioned in the embodiment of the present disclosure may be both straight sides. When the side of the first openwork opening LK1 extending along the second direction D2 coincides with the first side B1 or the second side B2 of the light-shielding member 41, it may mean that the first side B1 or the second side B2 of the first light-shielding member 41 may overlap with the straight line extending in the second direction D2. When one of the two sides of the first openwork opening LK1 extending in the second direction D2 is arranged to coincide with the first side B1 or the second side B2 of the first light-shielding member 41, the first openwork opening LK1 may be connected with the matrix opening K1. When the light-emitting material layer below the matrix opening K1 emits light, more of the emitted light may be concentrated in the area corresponding to the matrix opening K1, and the amount of light may become smaller toward a larger viewing angle. When the first openwork opening LK1 is connected to the matrix opening K1, the light emitted by the light-emitting material layer from the first openwork opening LK1 may be closer to the front view angle, which may be beneficial to increasing the amount of light emitted from the first openwork opening LK1 and improving the overall light output of the display panel.

Further, referring to FIGS. 9-10, in one embodiment of the present disclosure, in the third direction D3, the width of the first light-shielding member 41 provided with the first openwork opening LK1 may be different.

When the first openwork opening LK1 is introduced into the first light-shielding member 41, it may be equivalent to hollowing out at least a portion of the first light-shielding member 41. Therefore, in the first light-shielding member 41, the width of the area without disposing the first openwork member in the third direction D3 may be larger, while the width of the area provided with the first openwork member in the third direction D3 may be smaller. The area with the reduced width may be adjacent to the first openwork opening LK1, and a portion of the light emitted by the light-emitting material layer may be emitted from the first openwork opening LK1, thereby increasing the overall light output of the display panel.

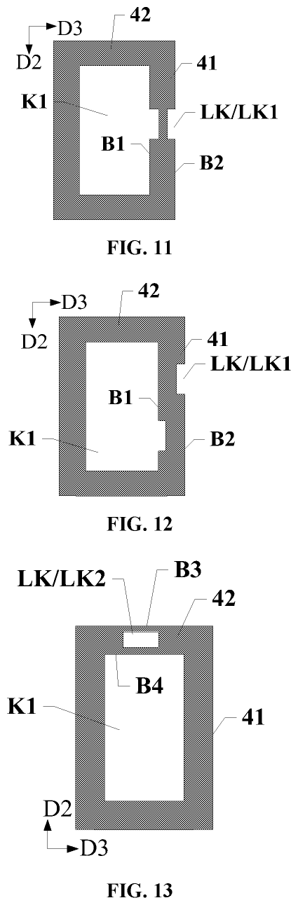

FIG. 11 shows another enlarged schematic diagram of the light-shielding member 40 corresponding to one matrix opening K1. This embodiment shows a solution in which one light-shielding member 40 may include two first openwork openings LK1.

In one embodiment of the present disclosure, a first light-shielding member 41 may include two first openwork openings LK1. The two first openwork openings LK1 may at least partially overlap in the third direction D3.

When two first openwork openings LK1 are provided on the same first light-shielding member 41, the two first openwork openings LK1 may be arranged in an overlapping manner in the third direction D3 as shown in FIG. 10. It should be noted that when two first openwork openings LK1 are provided on the first light-shielding member 41, both first openwork openings LK1 may need to avoid the metal wiring in the display panel. For example, no metal wiring is provided in the projection area of the first openwork opening LK1 in the first direction D1. When two first openwork openings LK1 are provided on the same first light-shielding member 41, it may be beneficial to increase the total area of the first openwork openings LK1 on the first light-shielding member 41. Thus, it may be beneficial to increase the amount of light emitted from the first openwork opening LK1 and to improve the overall transmittance of the display panel.

FIG. 12 shows another enlarged schematic diagram of the light-shielding member 40 corresponding to one matrix opening K1. This embodiment shows another solution in which one light-shielding member 40 includes two first openwork openings LK1.

As shown in FIG. 12, in one embodiment of the present disclosure, a first light-shielding member 41 may include two first openwork openings LK1, and the two first openwork openings LK1 may be staggered in the second direction D2.

The embodiment shown in FIG. 12 shows that when two first openwork openings LK1 are provided on the same first light-shielding member 41, among the two first openwork openings LK1, an edge of one first openwork opening LK1 in the second direction D2 and the first side B1 of the first light-shielding member 41 may overlap, and the edge of the other first openwork opening LK1 in the second direction D2 may overlap with the second side B2 of the first light-shielding member 41. In some other embodiments of the present disclosure, when two first openwork openings LK1 are provided on the same first light-shielding member 41, the edges of the two first openwork openings LK1 extending along the second direction D2 may also be coincided with a same side of the first light-shielding member 41 extending in the second direction D2 (the first side B1 or the second side B2). It should be noted that when the two first openwork openings LK1 are provided on the first light-shielding member 41, both first openwork openings LK1 may need to avoid the metal wiring in the display panel. For example, no metal wiring may need to be provided in the projection area of the first openwork openings LK1 along the first direction D1. Providing two first openwork openings LK1 on the same first light-shielding member 41 and staggering the two first openwork openings LK1 in the second direction D2 may also be conducive to improving the transmittance of the display panel and improving the overall light output amount of the display panel.

The above embodiments show the solutions of providing the first openwork opening LK1 on the first light-shielding member 41. In some other embodiments of the present disclosure, the openwork opening LK may also be provided on the second light-shielding member 42, or both the first light-shielding member 41 and the second light-shielding member 42 are provided with the openwork openings LK at the same time. The solution of providing the openwork opening LK on the second light-shielding member 42 will be described below.

FIG. 13 shows another enlarged schematic diagram of the light-shielding member 40 corresponding to a matrix opening K1. This embodiment shows a solution of providing the second openwork opening LK2 on the second light-shielding member 42.

As shown in FIG. 13, in one embodiment of the present disclosure, the openwork opening LK may include at least one second openwork opening LK2 located in the second light-shielding member 42. The second openwork opening LK2 may include two sides extending along the third direction D3.

The second light-shielding member 42 may include a third side B3 and a fourth side B4 that are oppositely arranged along the second direction D2 and extend along the third direction D3. At least one side of the second openwork opening LK2 extending along the third direction D3 may be located between the third side B3 and the fourth side B4.

Assuming that the openwork opening LK provided on the first openwork member is the second openwork opening LK2, this embodiment may limit the specific shape of the second openwork opening LK2. The second light-shielding member 42 may extend entirely in the third direction D3. In one embodiment, the long axis direction of the second openwork opening LK2 may be the third direction D3. The two sides of the second light-shielding member 42 extending in the third direction D3 may be respectively the third side B3 and the fourth side B4. The second openwork opening LK2 may also include two sides extending along the third direction D3, and at least one of the two sides may be located between the third side B3 and the fourth side B4 of the second light-shielding member 42. When the long axis direction of the second openwork opening LK2 provided on the second light-shielding member 42 is arranged in the extending direction of the second light-shielding member 42, the area of the second openwork opening LK2 may be appropriately increased and the manufacturing difficulty of the second openwork opening LK2 may be reduced appropriately. Accordingly, it may also be conducive to improving the transmittance of the display panel when the area of the second openwork opening LK2 increases.

Further, referring to FIG. 13, in one embodiment of the present disclosure, the two sides extending in the third direction D3 of the second openwork opening LK2 may be both located between the third side B3 and the fourth side B4.

Referring to FIG. 4 and FIG. 13, when the two sides of the second openwork

opening LK2 extending along the second direction D2 are arranged between the third side B3 and the fourth side B4 of the third light-shielding member 40, the second openwork opening LK2 may not be connected to the matrix opening K1. When the light-emitting material layer on the side of the matrix opening K1 facing toward the display layer 10 emits light, most of the light may pass through the matrix opening K1 and be directed to the light-exiting surface of the display panel, and some of the light may be able to irradiate toward the light-exiting surface of the display panel through the second openwork opening LK2, which may be beneficial to increasing the transmittance of the display panel and increasing the overall light-emitting amount of the display panel.

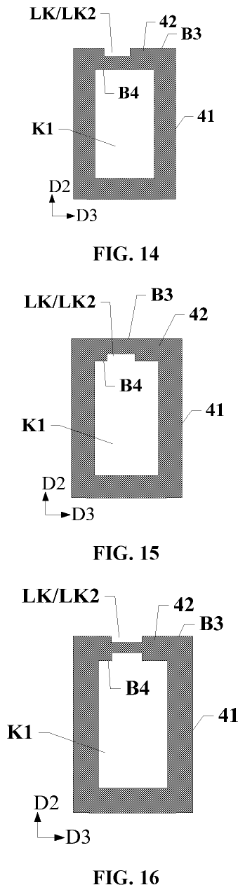

FIG. 14 and FIG. 15 respectively show another enlarged schematic view of the light-shielding member 40 corresponding to a matrix opening K1. The difference between the two may include that the position of the second openwork opening LK2 on the second light-shielding member 42 may be different. For example, the embodiment shown in FIG. 14 shows a solution in which one side of the second openwork opening LK2 extending in the third direction D3 may coincide with the third side B3 of the second light-shielding member 42. The embodiment shown in FIG. 15 shows a solution in which one side of the second openwork opening LK2 extending along the third direction D3 may coincide with the fourth side B4 of the second light-shielding member 42.

As shown in FIGS. 14-15, in one embodiment of the present disclosure, one of the sides of the second openwork opening LK2 extending along the third direction D3 may be located between the third side B3 and the fourth side B4. The other side of the openwork opening LK2 extending along the third direction D3 may coincide with the third side B3 or the fourth side B4. It should be noted that the third side B3 and the fourth side B4 of the first light-shielding member 41 mentioned in the embodiment of the present disclosure may be both straight sides. When the side of the second openwork opening LK2 extending along the third direction D3 coincides with the third side B3 or the fourth side B4 of the light-shielding member 41, it may mean that the third side B3 or the fourth side B4 of the first light-shielding member 41 may overlap with the linear side of the first light-shielding member 41 extending along the third direction D3. When one of the sides of the second openwork opening LK2 extending along the third direction D3 is set to coincide with the third side B3 or the fourth side B4 of the first light-shielding member 41, the second openwork opening LK2 may be connected with the matrix opening K1. When the light-emitting material layer below the matrix opening K1 emits light, more of the emitted light may be concentrated in the area corresponding to the matrix opening K1, and the amount of light toward a larger viewing angle may become smaller. When the second openwork opening LK2 is connected to the matrix opening K1, the light emitted by the light-emitting material layer from the second openwork opening LK2 is closer to the front view angle, which may be beneficial to increasing the amount of light emitted from the second openwork opening LK2 and improving the overall light output of the display panel.

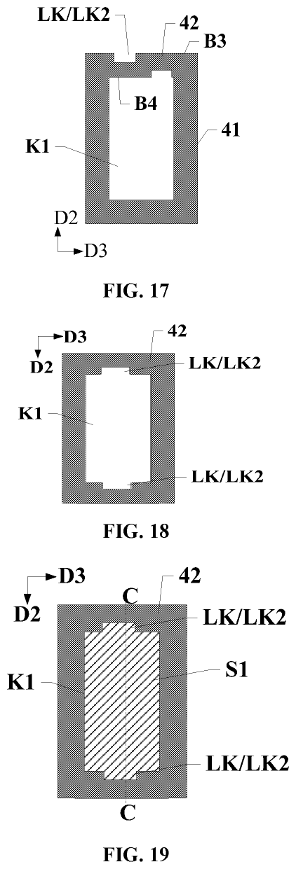

FIG. 16 and FIG. 17 respectively show another enlarged schematic view of the light-shielding member 40 corresponding to a matrix opening K1. This embodiment shows a solution in which a second light-shielding member 42 includes two second openwork openings LK2.

When two second openwork openings LK2 are provided on the same second light-shielding member 42, the two second openwork opening LK2 may be arranged overlapping in the second direction D2 as shown in FIG. 16, or may be arranged in a staggered arrangement in the third direction D3 as shown in FIG. 17. It should be noted that when two second openwork openings LK2 are provided on the second light-shielding member 42, the two second openwork openings LK2 may need to avoid the metal wiring in the display panel. For example, no metal wirings are provided in the projection area of the second openwork openings LK2 along the first direction D1. When two second openwork openings LK2 are provided on the same second light-shielding member 42, it may be beneficial to increase the total area of the second openwork openings LK2 on the second light-shielding member 42, thus it may be beneficial to increase the amount of light emitted from the second openwork opening LK2 and thus may be conducive to improving the overall transmittance of the display panel.

The embodiments shown in FIG. 16 and FIG. 17 shows that when two second openwork openings LK2 are provided on the same second light-shielding member 42, among the two second openwork openings LK2, one second openwork opening LK2 may be along the third direction D3. The edge of the second openwork opening LK2 may coincide with the third side B3 of the second light-shielding member 42, and the edge of the other second openwork opening LK2 along the third direction D3 may coincide with the fourth side B4 of the second light-shielding member 42. In some other embodiments of the present disclosure, when two second openwork openings LK2 are provided on the same second light-shielding member 42, the edges of the two second openwork openings LK2 extending along the third direction D3 may also be coincided with a same side of the second light-shielding member 42 extending in the third direction D3 (the third side B3 or the fourth side B4).

In one embodiment, when the second openwork opening LK2 is provided on the second light-shielding member 42, along the third direction D3, the width of the second openwork opening LK2 may be smaller than the width of the matrix opening K1.

FIG. 18 shows a schematic diagram in which a second openwork opening LK2 is provided on two second light-shielding members 42 adjacent to the same matrix opening K1.

As shown in FIG. 18, in one embodiment of the present disclosure, the two second light-shielding members 42 arranged on opposite sides of the same matrix opening K1 in the second direction D2 and adjacent to the same matrix opening K1 may both include the second openwork opening LK2. The second openwork opening LK2 may be connected with the matrix opening K1, and the two second openwork openings LK2 may be symmetrically arranged on both sides of the matrix opening K1.

Specifically, this embodiment shows the scheme that two second openwork openings LK2 are symmetrically arranged on the two second light-shielding members 42 adjacent to the same matrix opening K1, and the two second openwork openings LK2 may be symmetrically arranged. The two symmetrically arranged second openwork openings LK2 may be both connected to the matrix opening K1. By increasing the number of the second openwork openings LK2, it may be beneficial to increase the amount of light emitted from the second openwork openings LK2, thereby conducive to improving the transmittance of the display panel. In addition, when the two second openwork openings LK2 are arranged in a symmetrical manner on both sides of the same matrix opening K1, the amount of light emitted from the two second openwork openings LK2 adjacent to the matrix opening K1 may be similar such that the light emitted by the matrix opening K1 and the second openwork opening LK2 connected with the matrix opening K1 may be relatively symmetrical, which may be beneficial to reducing the problem of partial display failure on the display panel.

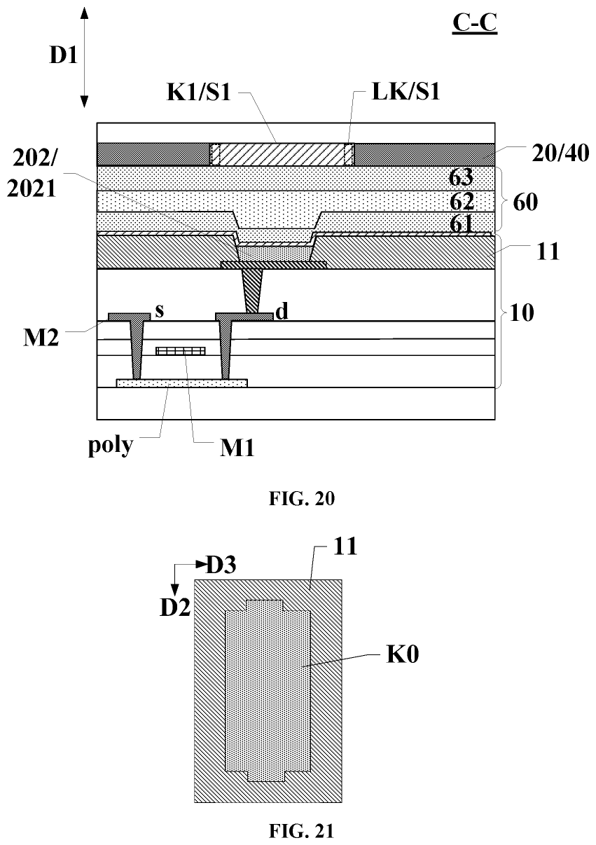

FIG. 19 shows a schematic diagram of filling the second openwork opening LK2 in FIG. 18 with a color resistor. FIG. 20 shows a CC-sectional view corresponding to FIG. 19.

As shown in FIGS. 19-20, in one embodiment of the present disclosure, the matrix opening K1 and the second openwork opening LK2 connected to the matrix opening K1 may be filled with the first color resistor S1, and the pixel opening K0 overlapping the matrix opening K1 may be filled with the first light-emitting material layer 2021. The color of the first color resistor S1 may be the same as the light-emitting color of the first light-emitting material layer 2021.

Specifically, when the matrix opening K1 is provided on the black matrix layer 20, the matrix opening K1 and the pixel opening K0 may be provided correspondingly. A first color light-emitting material layer may be provided in the pixel opening K0, and the light emitted by the first light-emitting material layer may be emitted through the matrix opening K1. In this embodiment, a first color resistor S1 may be further provided in the matrix opening K1, and the color of the first color resistor S1 may be the same as the light-emitting color of the first light-emitting material layer 2021. The light emitted by the first light-emitting material layer 2021 may emit through the first color resistor S1 in the matrix opening K1. The first color resistor S1 may play a better color filtering role, which may be beneficial to improving the color purity of the light emitted through the matrix opening K1, and thus may be beneficial to improving the overall display effect of the display panel. When the second openwork opening LK2 connected to the matrix opening K1 is introduced, the embodiment of the present disclosure may fill the second openwork opening LK2 with the first color resistor S1 of the same color, the first color resistor S1 in the matrix opening K2 and the first color resistor S1 in the second openwork member LK2 may be manufactured in a same process, and the manufacturing process may be simplified. In addition, when the matrix opening K1 and the second openwork opening LK2 connected to the matrix opening K1 are filled with the same color resist, the color of the light emitted from the matrix opening K1 and the light emitted from the second openwork opening LK2 may be same, which may not be easy to have the mixing color issue, thus while improving the transmittance of the display panel, it may be more conducive to improving the color purity of the display panel.

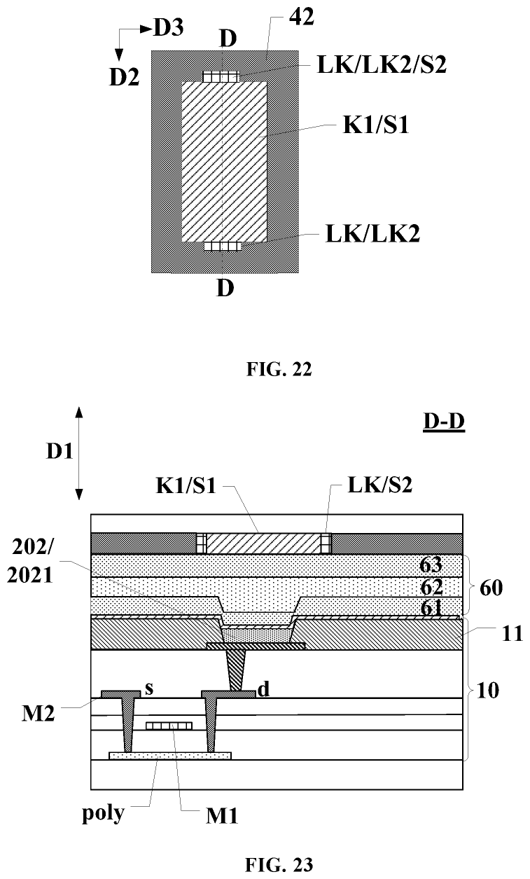

FIG. 21 shows a top view of the pixel opening K0 corresponding to the matrix opening K1 in FIG. 19 in the display panel provided by one embodiment of the present disclosure.

As shown in FIG. 21 and referring to FIG. 2, in one embodiment of the present

disclosure, in the first direction D1, the pixel opening K0 may overlap with the second openwork opening LK2.

When the second openwork opening LK2 connected to the matrix opening K1 is provided on the second light-shielding member 42, this embodiment further shows a solution of adaptively adjusting the shape of the pixel opening K0 corresponding to the matrix opening K1. Specifically, to set the outer contour shape of the pixel opening K0 to be same as the overall outer contour shape of the matrix opening K1 and the second openwork opening LK2, this embodiment is explained by taking the matrix opening K1 and the second openwork opening LK2 as both being rectangular as an example. The matrix opening K1 is a larger rectangular structure, and the second openwork opening LK2 may be a smaller rectangular structure arranged on both sides of the matrix opening K1 and may be connected with the matrix opening K1. Correspondingly, the pixel opening K0 may also be set as a combined structure of a larger rectangle (assumed to be the first rectangle) and two smaller rectangles (assumed to be the second rectangle) connected to the larger rectangle. In the first direction D1, the first rectangle may overlap with the matrix opening K1, and the second rectangle may overlap with the second openwork opening LK2. In this way, it may be equivalent to expanding the pixel opening K0 through the second rectangle, and the area of the pixel opening K0 may be increased. Because the color of the light-emitting material filled the pixel opening in K0 may be same as the color of the first color resistor S1 included in the matrix opening K1 and the second openwork opening LK2, the adaptive adjustment of the shape of the pixel opening K0 referring to the shape of the matrix opening K1 and the second openwork opening LK2 may be more conducive to improving the aperture ratio and transmittance of the display panel, and improving the display effect of the display panel.

It should be noted that when the color of the first color resistors S1 filled in the matrix opening K1 and the second openwork opening LK2 are both green color resistors, it may be beneficial to increase the amount of green color resistor contained in the display panel as a whole. Because the light emitted through the green color resistor may have a greater brightness, it may be beneficial to improve the overall brightness of the display panel. When the color of the first color resistor S1 filled in the matrix opening Kl and the second openwork opening LK2 are blue color, it may be beneficial to increase the amount of blue color resistor contained in the display panel as a whole. Because the blue color resistor may have a relatively large anti-reflective performance, increasing the amount of blue color resistors may help to improve the overall anti-reflective performance of the display panel.

The above embodiment shows a solution of filling the first color resistors S1 of a same color in the matrix opening K1 and the second openwork opening LK2 connected with the matrix opening K1. In some other embodiments of the present disclosure, the color of the color resistor filled in the second openwork opening LK2 may also be different from the color of the color resistor filled in the matrix opening K1, as shown in FIG. 22. FIG. 22 shows another scheme that the second openwork opening LK2 in FIG. 18 is filled with a color resistor. FIG. 23 shows a DD-sectional view corresponding to FIG. 22.

As shown in FIG. 22, in one embodiment of the present disclosure, the matrix opening K1 may be filled with the first color resistor S1, and the pixel opening K0 overlapping the matrix opening K1 may be filled with the first light-emitting material layer 2021. The color of the first color resistor S1 may be same as the light-emitting color of the first light-emitting material layer 2021. The second openwork opening LK2 may be filled with a second color resistor S2, and the second color resistor S2 may be a green color resistor or a blue color resistor.

Specifically, this embodiment takes the solution of the color resistor color filled in the matrix opening K1 and the second hollow port LK2 connected to the matrix opening K1 as an example. The first color resistor S1 may be a red color resistor, and the second color resistor S2 may be a green color resistor or a blue color resistor. In another embodiment, the first color resistor S1 may be a green color resistor, and the second color resistor S2 may be a blue color resistor. In another embodiment, the first color resistor S1 may be a green color resistor, and the second color resistor S2 may be a blue color resistor. In another embodiment, the first color resistor S1 may be a blue color resistor, and the second color resistor S2 may be a green color resistor. When the second color resistor S2 filled in the second openwork opening LK2 is a blue color resistor, because the blue color resistor may have a better anti-reflective performance, it may be beneficial to improve the overall anti-reflective performance of the display panel. When the second color resistor S2 filled in the second openwork opening LK2 is a green color resistor, because the light emitted through the green color resistor may have a higher brightness, it may be beneficial to improve the overall brightness of the display panel.

It should be noted that when the colors of the color resistors filled in the matrix opening K1 and the second openwork opening LK2 connected to the matrix opening K1 are different, the color resistors of the two colors may be formed separately. Assume that the first color resistor S1 in the matrix opening K1 is a red color resistor, and the second color resistor S2 in the second openwork opening LK2 connected to the matrix opening K1 is a green color resistor, in the actual manufacturing process, the first color resistor S1 may be formed during forming the red color resistor of the display panel, and the second color resistor S2 may be formed during forming the green color resistor of the display panel. For example, the second color resistor S2 in the second openwork opening LK2 may be formed during the same fabrication process as the color resistors of the same color in the display panel. Accordingly, there may be no need to introduce a separate manufacturing process for the second color resistor S2 in the second openwork opening LK2, which may be conducive to simplifying the manufacturing process when introducing the second color resistor S2 and improving the overall production efficiency of the display panel.

FIG. 24 shows another exemplary top view of the pixel opening K0 corresponding to the matrix opening K1 in FIG. 19 in the display panel provided by one embodiment of the present disclosure. This embodiment shows the matrix opening K1 and the third pixel opening K1 connected to the matrix opening K1. The overall outline shape of the second openwork opening LK2 may be different from the outer outline shape of the pixel opening K0.

As shown in FIG. 24 and referring to FIG. 4 and FIG. 19, in one embodiment of the present disclosure, along the first direction D1, the pixel opening K0 and the second openwork opening LK2 may not overlap.

Specifically, the area of the pixel opening K0 shown in this embodiment may be smaller than the total area of the matrix opening K1 and the second openwork opening LK2 corresponding to the pixel opening K0, and the orthographic projections of the pixel opening K0 and the second openwork opening LK2 on the display panel may not overlap. The edge of the orthographic projection of the pixel opening K0 adjacent to the second openwork opening LK2 may be partially retracted. In this way, it may be equivalent to increasing the distance between the orthographic projection of the color resistor in the second openwork opening LK2 and the orthographic projection of the light-emitting material layer in the pixel opening K0. When the color resistors filled the light-emitting material layer in the pixel opening K0 and in the second openwork opening LK2 are of different colors, increasing the distance between the light-emitting material layer and the corresponding color resistor in the second openwork opening LK2 may be beneficial to reduce the risk of the color mixing problem caused when the light emitted by the light-emitting material layer irradiates the color resistor in the second openwork opening LK2. Accordingly, it may be beneficial to improving the color purity of the display panel and thus may be beneficial to improving the display effect of the display panel.

In one embodiment, it is assumed that when the pixel opening K0 is not recessed, its shape and size may be same as the matrix opening K1. When the pixel opening K0 is recessed, the orthographic projection of the recessed area may be adjacent to the second openwork opening LK2. When two second openwork openings LK2 are provided, the pixel opening K0 may also be provided with two recessed parts. In one embodiment, the size of the recessed part may be greater than or equal to the size of the adjacent second openwork opening LK2 to minimize the possibility of color mixing.

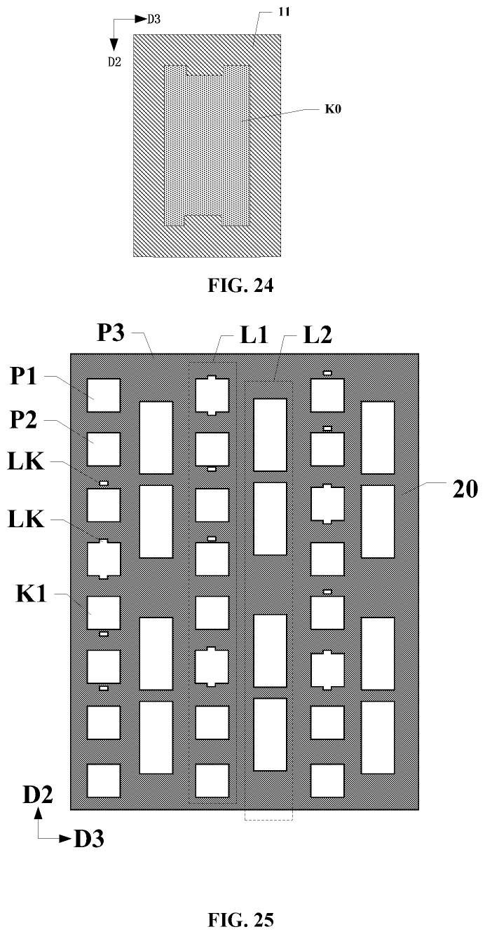

FIG. 25 shows a schematic diagram of an exemplary arrangement of sub-pixels and openwork openings LK provided by one embodiment of the present disclosure. As shown in FIG. 25, in one embodiment of the present disclosure, the display panel may include a plurality of first pixel columns L1 and second pixel columns L2 that are alternately arranged in the direction D2. The first pixel columns L1 may include first color sub-pixels P1 and second color sub-pixels P2 arranged along the third direction D3. The second pixel columns L2 may include third color sub-pixels P3 that are arranged along the third direction D3. The second direction D2 and the third direction D3 may intersect. The orthographic projection of at least a portion of the openwork opening LK on the substrate may be located between the orthographic projections of the pixel openings K0 corresponding to the first color sub-pixel P1 and the second color sub-pixel P2 on the substrate 00.

It should be noted that, to clearly illustrate the positional relationship between the openwork openings and the matrix openings, this embodiment does not fill the matrix openings corresponding to the sub-pixels of different colors. The pixel arrangement structure shown in this embodiment is only for illustration and does not limit the actual pixel arrangement structure and pixel shape of the display panel. In some other pixel structures, the openwork opening LK may also be provided on the top of the light-shielding member 40 on the black matrix layer 20 to improve the transmittance of the display panel. FIG. 24 illustrates the staggered arrangement of the third color sub-pixels P3 in the second pixel column L2 located on both sides of the same first pixel column L1 but does not limit the arrangement of the third color sub-pixels P3 in the different second pixel columns L2.

Further, referring to FIG. 25, this embodiment is explained by taking a display panel including first pixel columns L1 and second pixel columns L2 alternately arranged along the second direction D2 as an example. The first pixel column L1 may include two color sub-pixels, which may be first color sub-pixels P1 and second color sub-pixels P2, respectively. The second pixel column L2 may include sub-pixels of one color, i.e., third color sub-pixels P3. When the openwork opening LK is formed on the light-shielding member 40, in one embodiment, the openwork opening LK may be located between the pixel openings K0 corresponding to the first color sub-pixel P1 and the second color sub-pixel P2 in the first pixel column L1, for example, located on the light-shielding member 40 between the sub-pixels in the first pixel column L1. When the pixel arrangement structure shown in FIG. 25 is adopted, the area between the first color sub-pixel P1 and the second color sub-pixel P2 in the first pixel column L1 may include the space to dispose the openwork opening LK. Thus, this embodiment may rationally utilize the space to dispose the openwork opening LK, the transmittance of the display panel may be effectively increased.

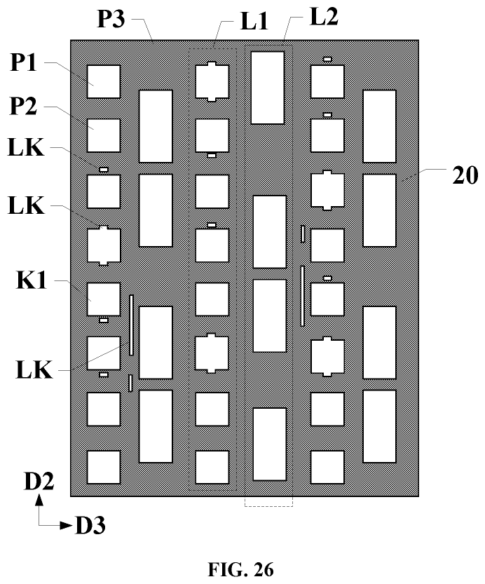

FIG. 26 shows the schematic diagram of another exemplary arrangement of sub-pixels and openwork openings LK provided by one embodiment of the present disclosure. As shown in FIG. 26, in one embodiment of the present disclosure, the display panel may include a plurality of first pixel columns L1 and second pixel columns L2 that are alternately arranged in the second direction D2. The first pixel column L1 may include the first color sub-pixels P1 and the second color sub-pixels P2 arranged along the third direction D3. The second pixel column L2 may include third color sub-pixels P3 arranged along the third direction D3. The second direction D2 and the third direction D3 may intersect. The orthographic projection of at least a portion of the openwork opening LK on the substrate may be located between the pixel openings K0 corresponding to the first pixel columns L1 and the pixel opening K0 corresponding to the second pixel columns L2.

Specifically, when the pixel arrangement structure is embodied as the structure shown in FIG. 26, the openwork opening LK may also be set on a light-shielding member 40 between the adjacent first pixel column L1 and the second pixel column L2 according to the actual spatial arrangement. The embodiment of the present disclosure does not limit the specific position of the openwork opening LK on the light-shielding member 40 between the first pixel column L1 and the second pixel column L2. It should be noted that when the openwork opening LK is provided between two adjacent pixel columns, the openwork opening LK may need to avoid the wiring extending along the third direction D3 in the display panel. This embodiment may rationally utilize the space of the display panel and effectively improve the transmittance of the display panel by arranging openwork openings LK between adjacent pixel columns.

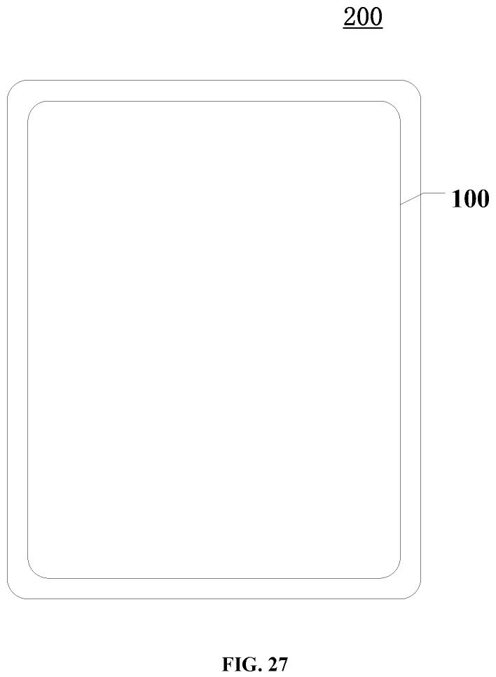

The present disclosure also provides a display device. The display device may include the display panel provided in the above embodiments of the present disclosure. FIG. 27 is a schematic structural diagram of an exemplary display device according to various disclosed embodiments of the present disclosure. As shown in FIG. 27, the display device 200 may include the display panel 100 provided by any of the above embodiments of the present disclosure.

It can be understood that the display device provided by the embodiment of the present disclosure may be a computer, a mobile phone, a tablet, or other display device with a display function, and the present disclosure is not specifically limited to this. The display devices provided by the embodiments of the present disclosure may include the beneficial effects of the display panels provided by the embodiments of the present disclosure, the details may be referred to the specific description of the display panel in the above embodiments, and this embodiment will not be described again here.

It can be seen from the above embodiments that the display panel and display device provided by the present disclosure may at least achieve the following beneficial effects.

In the display panel and display device provided by the present disclosure, a black matrix layer may be provided on a side of the display layer facing away from the substrate. The pixel definition layer may define a plurality of pixel openings. A light-emitting material layer may be provided in the pixel openings. The matrix openings on the black matrix layer may overlap with the pixel openings such that the light emitted by the light-emitting material layer in the pixel openings may be emitted to the light-exiting surface of the display panel through the matrix openings. The black matrix layer may also include a light-shielding member that does not overlap with the pixel opening, and an openwork opening may be provided on the light-shielding member. At least a portion of the light emitted by the light-emitting material layer in the pixel definition layer, such as the large viewing angle light, may be emitted from the above-mentioned openwork opening. The introduction of the openwork opening may be beneficial to increasing the transmittance of the entire display product.

Although some specific embodiments of the disclosure have been described in detail by way of examples, those skilled in the art will understand that the above examples are for illustration only and are not intended to limit the scope of the disclosure. Those skilled in the art will understand that the above embodiments can be modified without departing from the scope and spirit of the disclosure. The scope of the disclosure is defined by the appended claims.

What is claimed is:

1. A display panel, comprising:
a substrate, and a display layer and a black matrix layer sequentially arranged on a same side of the substrate,
wherein:
the display layer includes a pixel definition layer;
the pixel definition layer defines a plurality of pixel openings;
in a first direction, the plurality of pixel openings pass through the pixel definition layer;
the first direction is perpendicular to a plane where the substrate is located;
the black matrix layer includes a matrix opening that overlaps with a pixel opening of the plurality of pixel openings in the first direction and a light-shielding member that does not overlap with the pixel opening in the first direction;
the light-shielding member includes an openwork opening; and
the matrix opening and the openwork opening are both located in a display area of the display panel.

2. The display panel according to claim 1, further comprising:
a touch layer located between the display layer and the black matrix layer;
wherein:
the touch layer includes a plurality of touch electrodes, and the touch electrodes include a plurality of electrically connected metal line segments;
in the first direction, orthographic projections of the metal line segments on the plane where the substrate is located do not overlap with orthographic projections of the pixel opening, the matrix opening and the openwork opening on the plane; and
the orthographic projections of the metal line segments on the substrate is located within an orthographic projection of the light-shielding member on the substrate.

3. The display panel according to claim 1, wherein the light-shielding member comprises:
first light-shielding members and second light-shielding members that are intersectingly arranged,
wherein:
the first light-shielding members extend in a second direction and are arranged in a third direction; the second light-shielding members extend in the third direction and are arranged in the second direction; and the second direction and the third direction intersect each other; and
the openwork opening is located in the first light-shielding member and/or the second light-shielding member.

4. The display panel according to claim 3, wherein the openwork opening comprises:
at least one first openwork opening located at the first light-shielding member and including two sides extending in the second direction, wherein the first light-shielding member includes a first side and a second side oppositely disposed in the third direction and extending in the second direction, and at least one of the two sides of the first openwork opening extending in the second direction is located between the first side and the second side.

5. The display panel according to claim 4, wherein:
the two sides of the first openwork opening extending in the second direction are both located between the first side and the second side.

6. The display panel according to claim 4, wherein:
one side of the first openwork opening extending in the second direction is located between the first side and the second side; and
another side of the first openwork opening extending in the second direction coincides with the first side or the second side.

7. The display panel according to claim 6, wherein:
a width of the first light-shield member disposed with the first openwork opening is different in the third direction.

8. The display panel according to claim 6, wherein:
the first light-shielding member includes two first openwork openings; and
in the second direction, the two first openwork openings at least partially overlap.

9. The display panel according to claim 6, wherein:
the first light-shielding member includes two first openwork openings; and
in the second direction, the two first openwork openings are alternatively distributed.

10. The display panel according to claim 3, wherein:
the openwork opening includes at least one second openwork opening located in the second light-shielding member;
the second openwork opening includes two sides extending in the third direction;
the second light-shielding member includes a third side and a fourth side that are oppositely arranged in the second direction and extending in the third direction; and
at least one side of the second openwork opening extending in the third direction is located between the third side and the fourth side.

11. The display panel according to claim 10, wherein:
both the two sides of the second openwork opening extending in the third direction are located between the third side and the fourth side.

12. The display panel according to claim 10, wherein:
one side of the second openwork opening extending in the third direction is located between the third side and the fourth side; and
another side of the second openwork opening extending in the third direction coincides with the third side or the fourth side.

13. The display panel according to claim 12, wherein:
two second light-shielding members disposed on opposite sides of a same matrix opening in the second direction and adjacent to the same matrix opening all include a second openwork opening;
the second openwork openings are connected with the matrix opening; and
the two second openwork openings are symmetrically arranged at both sides of the matrix opening.

14. The display panel according to claim 13, wherein:
the matrix opening and the second openwork opening connected to the matrix opening are filled with a first color resistor;
the pixel opening overlapping the matrix opening is filled with a first light-emitting material layer; and
a color of the color resist is same as a light-emitting color of the first light-emitting material layer.

15. The display panel according to claim 14, wherein:
in the first direction, the pixel opening overlaps with the second openwork opening.

16. The display panel according to claim 13, wherein:
the matrix opening is filled with a first color resistor;
the pixel opening overlapping the matrix opening is filled with a first light-emitting material layer;
a color of the color resist is same as a light-emitting color of the first light-emitting material layer;
the second openwork opening is filled with a second color resist; and
the second color resist is a green color resist or a blue color resist.

17. The display panel according to claim 16, wherein:
in the first direction, the pixel opening does not overlap with the second openwork opening.

18. The display panel according to claim 1, comprising:
a plurality of first pixel columns and a plurality of second pixel columns alternately arranged in a second direction;
wherein:
the plurality of first pixel columns include first color sub-pixels and second color sub-pixels arranged in a third direction;
the plurality of second pixel columns include third color sub-pixels arranged in the third direction;
the second direction intersects with the third direction; and
an orthographic projection of at least a portion of the openwork opening on the substrate is located between orthographic projections of the pixel openings corresponding to the first color sub-pixels and the second color sub-pixels on the substrate.

19. The display panel according to claim 1, comprising:
a plurality of first pixel columns and a plurality of second pixel columns alternately arranged in a second direction;
wherein:
the plurality of first pixel columns include first color sub-pixels and second color sub-pixels arranged in a third direction;
the plurality of second pixel columns include third color sub-pixels arranged in the third direction;
the second direction intersects with the third direction; and
an orthographic projection of at least a portion of the openwork opening on the substrate is located between the pixel openings corresponding to the plurality of first pixel columns and pixel openings corresponding to the plurality of second pixel columns.

20. A display device, comprising:
a display panel, including:
a substrate, and a display layer and a black matrix layer arranged sequentially on a same side of the substrate,
wherein:
the display layer includes a pixel definition layer;
the pixel definition layer defines a plurality of pixel openings;
in a first direction, the plurality of pixel openings pass through the pixel definition layer;
the first direction is perpendicular to a plane where the substrate is located;
the black matrix layer includes a matrix opening that overlaps with a pixel opening of the plurality of pixel openings in the first direction and a light-shielding member that does not overlap with the pixel opening in the first direction;
the light-shielding member includes an openwork opening; and
the matrix opening and the openwork opening are both located in a display area of the display panel.
